(19) United States
(12) Patent Application Publication
(10) Pub. No.: US 2024/0387163 A1
(43) Pub. Date: Nov. 21, 2024

(54) METHOD FOR DRYING WAFER

(71) Applicant: NATIONAL SUN YAT-SEN UNIVERSITY, Kaohsiung City (TW)

(72) Inventors: TING-CHANG CHANG, Kaohsiung City (TW); CHUAN-WEI KUO, Kaohsiung City (TW); SHENG-YAO CHOU, Kaohsiung City (TW); SHIH-KAI LIN, Kaohsiung City (TW); HUNG-MING KUO, Kaohsiung City (TW); YU-BO WANG, Kaohsiung City (TW); PEI-JUN SUN, Kaohsiung City (TW)

(21) Appl. No.: 18/219,337

(22) Filed: Jul. 7, 2023

(30) Foreign Application Priority Data
May 16, 2023 (TW) 112118065

(51) Int. Cl. H01L 21/02

(52) U.S. Cl. CPC H01L 21/02057; H01L 21/67034

(57) ABSTRACT

A method for drying a wafer includes a cleaning step, a liquid replacing step, and a drying step. In the cleaning step, a workpiece located in a process chamber is cleaned with a cleaning solution. In the liquid replacing step, a drying agent in gas phase is compressed to convert into liquid phase, and the drying agent in liquid phase is introduced to the process chamber to replace the cleaning solution. In the drying step, the cleaning solution is discharged out of the process chamber, and then the drying agent is converted from liquid phase back to gas phase and is discharged out of the process chamber.

### CROSS REFERENCE TO RELATED APPLICATION

The application claims the benefit of Taiwan application serial No. 112118065, filed on May 16, 2023, and the entire contents of which are incorporated herein by reference.

### BACKGROUND OF THE INVENTION

### 1. Field of the Invention

The present invention relates to semiconductor manufacturing process and, more particularly, to a method for drying a wafer, which can prevent wafer structures from deforming or collapsing after cleaning.

### 2. Description of the Related Art

In the semiconductor industry, electronic components and the linewidth of the metal lines are miniaturized to maximize the area utilization of wafers. Laminated transistor structures are produced through semiconductor manufacturing processes that involve iterative steps such as material deposition on a wafer, application of photoresists, exposure to light, etching, etc. Prior to each layer-depositing step, it is necessary to remove the photoresists and polymers formed by the etching in the previous stage. It is done to prevent residual substances from interfering with the electrical connection of the subsequent laminated materials, which could result in devices with poor electrical properties. In such situations, it is especially difficult to completely remove the substances remaining in channel structures. Therefore, it is necessary to utilize wet cleaning methods to completely remove impurities and the chemicals used in the previous stage before proceeding with drying the wafer for subsequent processing.

As shown in FIG. 1, in a conventional method for drying a wafer, the solvent S is typically removed from the surface of a transistor T along with impurities. However, with the miniaturization of semiconductor devices, the pitch between transistors T on a wafer keeps decreasing, resulting in an increase of the aspect ratio of the wafer structures. As shown in FIG. 1, when cleaning a wafer with high aspect ratio structures, the surface tension of the solvent S exerts an inward pulling force on both sides of the transistors T as the solvent S evaporates and leaves the gap between the transistors T. This inward pulling force causes the transistors to collapse inwardly during the drying process, and thus degrades the yield of the semiconductor devices.

To address this issue, using supercritical fluid (SCF) to lower the surface tension of the cleaning solution used in the wet cleaning process has been suggested in this field. However, to maintain the state of SCF during the cleaning process, a high temperature and high pressure environment is required within the cleaning chamber or apparatus. Apart from imposing stringent requirements on the temperature and pressure resistance of the cleaning chamber or apparatus, the cost of maintaining such high temperature and high pressure environment is also a concern.

In light of this, it is necessary to improve the conventional method for drying a wafer.

### SUMMARY OF THE INVENTION

To solve the above problem, it is an objective of the present invention to provide a method for drying a wafer that can effectively clean and dry the wafer without causing the collapsing of wafer structures due to the high surface tension of the cleaning solution.

As used herein, the term “a”, “an” or “one” for describing the number of the elements and members of the present invention is used for convenience, provides the general meaning of the scope of the present invention, and should be interpreted to include one or at least one. Furthermore, unless explicitly indicated otherwise, the concept of a single component also includes the case of plural components.

A method for drying a wafer according to the present invention may include a cleaning step, a liquid replacing step, and a drying step. In the cleaning step, a workpiece located in a process chamber is cleaned with a cleaning solution. In the liquid replacing step, a drying agent in gas phase is compressed to convert into liquid phase, and the drying agent in liquid phase is introduced to the process chamber to replace the cleaning solution. In the drying step, the cleaning solution is discharged out of the process chamber, and then the drying agent is converted from liquid phase back to gas phase and is discharged out of the process chamber.

Thus, the method for drying a wafer of the present invention may involve compressing a drying agent in gas phase into liquid phase, and using the drying agent in liquid phase to replace a cleaning solution with a high surface tension. Thereafter, the drying agent in liquid phase may convert back to gas phase and be discharged out of the process chamber. This can achieve the effect of preventing the wafer structures from collapsing due to the high surface tension of the cleaning solution during drying.

In an example, a temperature of the process chamber is maintained between 20° C. and 30° C. Thus, maintaining the temperature of the process chamber within this range can reduce the time and cost for heating and/or cooling the cleaning chamber or apparatus during cleaning and drying of a wafer.

In an example, a pressure of the process chamber in the liquid replacing step is lower than a critical pressure of the drying agent. Thus, it can be ensured that the drying agent will not become supercritical liquid, lowering the requirements on the temperature and pressure resistance of the process chamber and the cost of the cleaning process.

In an example, the drying agent includes carbon dioxide, carbon tetrafluoride, nitrogen gas, argon gas, helium gas, neon gas, oxygen gas, sulfur hexafluoride, hexafluoroethane, butene, or monofluoromethane. Thus, by using these substances as the drying agent, the extent for increasing the pressure of the process chamber can be reduced, thereby lowering the cost of the cleaning process.

In an example, the cleaning solution includes isopropanol, acetone, ethanol, or hexane, and further includes hydrofluoroether. The volume of the hydrofluoroether is 1% or more of the cleaning solution. Thus, the cleaning solution has a higher solubility with the drying agent in liquid phase, allowing the cleaning solution to be effectively replaced and brought out of the process chamber by the drying agent in liquid phase.

In an example, in the liquid replacing step, a portion of the drying agent in liquid phase forms a sub-layer of a mixed solution with the cleaning solution, and a remaining portion of the drying agent forms a sub-layer of the drying agent. In the drying step, discharging the cleaning solution out of the process chamber is performed by discharging the mixed solution out of the process chamber. Thus, by forming the mixed solution, the cleaning solution can be effectively brought out of the process chamber by the drying agent.

In an example, the volumetric ratio of the cleaning solution to the drying agent in liquid phase is between 0:0.01 and 1:1000. Thus, by maintain the volumetric ratio of the cleaning solution to the drying agent in liquid phase within this range, the cleaning solution can be effectively brought out of the process chamber by the drying agent.

### BRIEF DESCRIPTION OF THE DRAWINGS

The present invention will become more fully understood from the detailed description given hereinafter and the accompanying drawings which are given by way of illustration only, and thus are not limitative of the present invention, and wherein:

FIG. 1 is a schematic view of a conventional method for drying a wafer that results in the collapse of the wafer structure.

FIG. 2 is a schematic view of a method for drying a wafer in accordance with the present invention.

FIG. 3 is a schematic view of the method for drying a wafer in accordance with the present invention.

FIG. 4 is a schematic view of the method for drying a wafer in accordance with another aspect of the present invention.

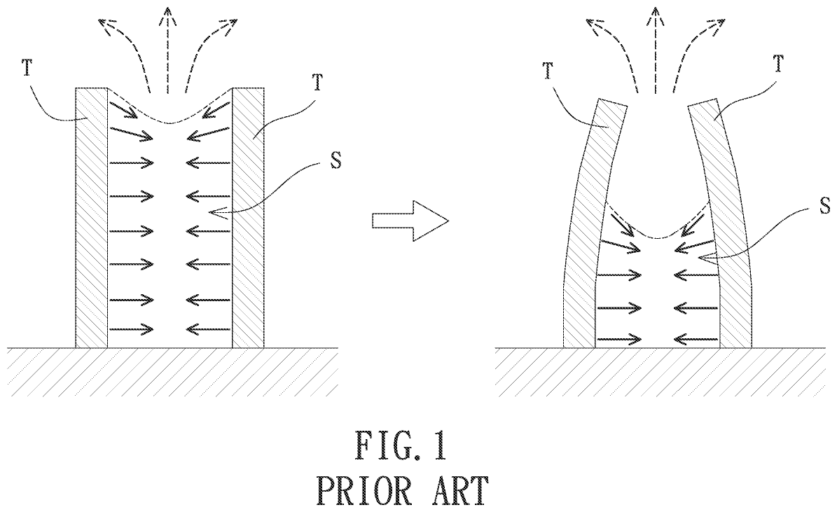

### DETAILED DESCRIPTION OF THE INVENTION

The method for drying a wafer of the present invention may include a cleaning step, a liquid replacing step, and a drying step.

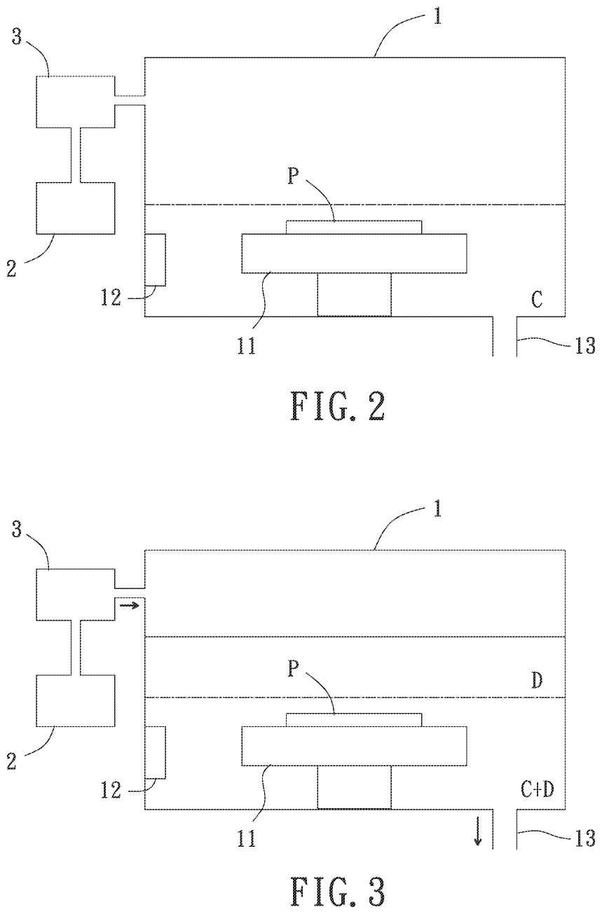

As shown in FIG. 2, in the cleaning step, a workpiece P may be disposed on a pedestal 11 in a process chamber 1. The workpiece P may be an unprocessed wafer and may also be a processed wafer having various protruded or recessed features (e.g., fin features) formed on the surface thereof by an etching process. In the case where the workpiece P is an unprocessed wafer, there may be impurities to be removed on the surface of the wafer; and in the case where the workpiece P is a processed wafer, there may be impurities and the chemicals used in the previous processing step remaining on the wafer. For removing the chemicals and impurities from the workpiece P, a cleaning solution C may be introduced into the process chamber 1 until the liquid level of the cleaning solution C is higher than a top surface of the workpiece P (e.g., the layer “C” as shown in FIG. 2). With the impurities or chemicals dissolve in the cleaning solution C, the workpiece P is cleaned. It is noted that, depending on the location to be cleaned of the workpiece P, the liquid level may be not higher than the top surface of the workpiece P, as long as the liquid level is higher than the location to be cleaned of the workpiece P. In this embodiment, the cleaning solution C may include isopropanol, acetone, ethanol, hexane, and any combination thereof. The cleaning solution C may also include a hydrofluoroether (HFE) solution, such as methyl perfluoropropyl ether, methyl nonafluoroisobutyl ether, or methyl nonafluorobutyl ether solutions, in which the HFE solution is preferably 1% or more (by volume) of the cleaning solution C.

In this embodiment, the cleaning step may be performed at a cleaning temperature that is higher than the freezing point (melting point) of the cleaning solution C and is lower than the boiling point of the cleaning solution C. For example, in an instance where the cleaning solution C is isopropanol, the cleaning temperature may range from −89° C. to 82.6° C. In a preferred embodiment, the cleaning temperature may range from 20° C. to 30° C., thereby decreasing the time and cost for heating and/or cooling the process chamber 1.

Next, in the liquid replacing step, a drying agent D in gas phase may be introduced from a drying agent source 2 into a pressurization device 3, by which the drying agent D is converted from gas phase to liquid phase. The drying agent D in liquid phase is then introduced into the process chamber 1 to replace the cleaning solution C. For example, in an embodiment, the drying agent source 2 may be a gas cylinder, in which the drying agent in gas phase is stored. In another embodiment, the drying agent source 2 may be a liquefied gas cylinder, in which the drying agent D is stored in a pressurized and liquid phase. In such case, the step of converting the drying agent from gas phase into liquid phase with the pressurization device 3 may be omitted, and the drying agent D in liquid phase may be directly introduced from the drying agent source 2 (i.e., the liquefied gas cylinder) into the process chamber 1. In this embodiment, the drying agent D may include carbon dioxide (CO₂), carbon tetrafluoride (CF₄), nitrogen gas (N₂), argon gas (Ar), helium gas (He), neon gas (Ne), oxygen gas (O₂), sulfur hexafluoride (SF₆), hexafluoroethane (C₂F₆), butene (C₄H₈, for example, 1-butene and/or 2-butene), or monofluoromethane (CH₃F). In an alternative embodiment, the drying agent may be a combination of any of the substances listed above, as long as the temperature and pressure ranges required to maintain these substances in the liquid phase partially overlap. For example, the temperature and pressure ranges for maintaining N₂ in liquid phase range from about −210° C. to −147° C. and from about 0.1 atm to 1500 atm, respectively; and those for maintaining Ar in liquid phase range from about 31 188° C. to −120° C. and from about 0.6 atm to 49 atm, respectively. Accordingly, the temperature and pressure ranges for simultaneously maintaining N₂ and Ar in liquid phase are from about −188° C. to −120° C. and from about 0.6 atm to 49 atm, respectively. N₂ and Ar may be mixed within such temperature and pressure ranges in any ratio, and the mixture may be used as the drying agent D.

The process pressure and temperature of the drying agent D may be controlled to ensure that the drying agent D can be maintained in the liquid phase and not convert into SCF when entering the process chamber 1. To achieve this, at least one of the following conditions for the process chamber 1 should be met: (i) the process pressure is maintained below the critical pressure of the drying agent D; and (ii) the process temperature is maintained below the critical temperature of the drying agent D. Furthermore, the process temperature is maintained above the freezing point of the cleaning solution C to prevent the cleaning solution C from freezing for the purpose of replacing the cleaning solution C with the drying agent D.

In a preferred embodiment, the process temperature may be equal to or substantially equal to the cleaning temperature to reduce the time and cost for heating and/or cooling. In such case, the process pressure may be controlled below the critical pressure of the drying agent D to ensure that the drying agent D will not become SCF after entering the process chamber 1.

A temperature/pressure sensor 12 may be disposed in the process chamber 1 to detect the process pressure and/or the process temperature, such that the process pressure and/or the process temperature may be controlled by a temperature/pressure control mechanism (not shown).

As shown in FIG. 3, the drying agent D may be introduced into the process chamber 1 and thoroughly mixed with the cleaning solution C. Since the drying agent D is partially soluble with the cleaning solution C, a portion of the drying agent D may form a sub-layer of a mixed solution (i.e., the layer “C+D” as shown in FIG. 3) with the cleaning solution C, and the remaining portion of the drying agent D that does not mix with the cleaning solution C may form a sub-layer of the drying agent D (i.e., the layer “D” as shown in FIG. 3). In this embodiment, the chosen drying agent D has a lower density than the cleaning solution C, resulting in the layer “D” being located above the layer “C+D.” In this embodiment, the volumetric ratio of the cleaning solution C to the drying agent D (in liquid phase) may range from 1:0.01 to 1:1000, such as 1:1 or 1:10. However, as known by one skilled in the art, the volumetric ratio of the cleaning solution C to the drying agent D (in liquid phase) may be adjusted in a suitable manner depending on the cleaning and drying requirements, and the type of the cleaning solution C and the drying agent D being selected.

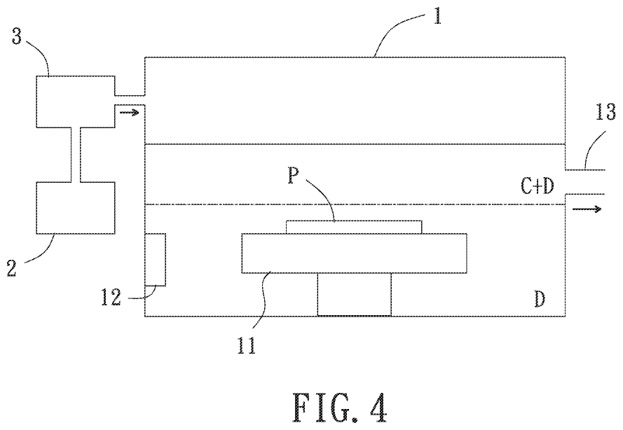

The mixed solution (i.e., all cleaning solution C and a portion of the drying agent D) may be discharged out of the process chamber 1 from a lower portion thereof by opening an outlet port 13 of the process chamber 1. It is noted that in an instance where the chosen drying agent D has a higher density than the cleaning solution C, the layer “D” is located below the layer “C+D.” In such case, the outlet port 13 of the process chamber may be disposed at an upper portion of the process chamber 1, and the mixed solution may be discharged from the upper portion of the process chamber 1. In addition, although there is only one outlet port 13 shown in FIG. 3 and FIG. 4, the process chamber 1 may have two outlet ports 13 located at the upper portion and the lower portion of the process chamber, respectively. In such case, the mixed solution may be discharged from the process chamber 1 by opening one of the two outlet ports 13 depending on the density relationship between the cleaning solution C and the drying agent D.

In the drying step, once the mixed solution is completely discharged out of the process chamber 1, the pressure of the process chamber 1 may be lowered, causing the remaining drying agent D to convert back to gas phase and be discharged from the process chamber 1. In this manner, the drying agent D may be removed from the process chamber 1, thereby completing the cleaning of the workpiece P without any additional heating steps. In a preferred embodiment, the pressure of the process chamber 1 is lowered to a range of 0.98 atm to 1.02 atm, such as about 1 atm, resulting in a reduction of the time and cost for further decreasing the pressure of the process chamber 1.

The following experiment was conducted to demonstrate the effectiveness of the method for drying a wafer of the present invention in addressing the issue of collapsing of wafer structures during cleaning-drying process of the wafer.

Experiment A: the impact of liquid drying agents on collapsing of wafer structures.

TABLE 1
Drying conditions and collapse ratio results in each group.

| Group | Cleaning Solution | Drying Agent | Collapse ratio |
|---|---|---|---|
| A0 | Ethanol | — | 100% |
| A1 | Ethanol | CO₂ | 15% |
| A2 | Ethanol + HFE | CO₂ | 0% |

Table 1 presents the collapse ratio results obtained from the Experiment A of the present invention. The experiment was conducted under the following conditions: the cleaning temperature of the process chamber 1 was maintained at 25° C., the process temperature was maintained at 25° C., and the process pressure ranged from 60 to 70 atm. In addition, the workpiece P used in this experiment is a wafer with fin structures. As shown in table 1, in group A0, only ethanol is used as the cleaning solution and no drying agent is used to replace the ethanol, resulting in natural evaporation of the ethanol. In such condition, the collapse ratio is 100%, showing that the high surface tension of the ethanol causes the features of the tested wafer to collapse during the wafer cleaning-drying process. In group A1, liquefied CO₂ is used as the drying agent to replace the ethanol, in which the volumetric ratio of the cleaning solution to the drying agent is 1:1. The collapse ratio for group A1 is 15%, showing that the use of liquefied CO₂ can lower the collapse ratio effectively. However, some fin structures still experienced collapsing despite the improvement. In group A2, liquefied CO₂ is used as the drying agent to replace the ethanol and HFE, in which the volumetric ratio of the ethanol to the HFE is 1:0.1. The collapse ratio for group A2 is 0%, showing that the method for drying a wafer of the present invention can effectively address the issue of collapsing of wafer structures during cleaning-drying process of a wafer.

In summary, the method for drying a wafer of the present invention may involve compressing a drying agent in gas phase into liquid phase, and using the drying agent in liquid phase to replace a cleaning solution with a high surface tension. Thereafter, the drying agent in liquid phase may convert back to gas phase and be discharged out of the process chamber. This can achieve the effect of preventing the wafer structures from collapsing due to the high surface tension of the cleaning solution during drying.

Although the invention has been described in detail with reference to its presently preferable embodiments, it will be understood by one of ordinary skill in the art that various modifications can be made without departing from the spirit and the scope of the invention, as set forth in the appended claims. Further, if the above-mentioned several embodiments can be combined, the present invention includes any implementation aspects of combinations thereof.

What is claimed is:

1. A method for drying a wafer, comprising:
a cleaning step, in which a workpiece located in a process chamber is cleaned with a cleaning solution;
a liquid replacing step, in which a drying agent in a gas phase is compressed to convert into a liquid phase, and the drying agent in the liquid phase is introduced to the process chamber to replace the cleaning solution; and
a drying step, in which the cleaning solution is discharged out of the process chamber, and then the drying agent is converted from the liquid phase back to the gas phase and is discharged out of the process chamber.

2. The method for drying the wafer as claimed in claim 1, wherein a temperature of the process chamber is maintained between 20° C. and 30° C.

3. The method for drying the wafer as claimed in claim 2, wherein a pressure of the process chamber in the liquid replacing step is lower than a critical pressure of the drying agent.

4. The method for drying the wafer as claimed in claim 1, wherein the drying agent includes carbon dioxide, carbon tetrafluoride, nitrogen gas, argon gas, helium gas, neon gas, oxygen gas, sulfur hexafluoride, hexafluoroethane, butene, or monofluoromethane.

5. The method for drying the wafer as claimed in claim 4, wherein the cleaning solution includes isopropanol, acetone, ethanol, or hexane, and further includes hydrofluoroether, and wherein a volume of the hydrofluoroether is 1% or more of the cleaning solution.

6. The method for drying the wafer as claimed in claim 5, wherein:
in the liquid replacing step, a portion of the drying agent in liquid phase forms a sub-layer of a mixed solution with the cleaning solution, and a remaining portion of the drying agent forms a sub-layer of the drying agent in the process chamber; and
in the drying step, discharging the cleaning solution out of the process chamber is performed by discharging the mixed solution out of the process chamber.

7. The method for drying the wafer as claimed in claim 1, wherein the volumetric ratio of the cleaning solution to the drying agent in liquid phase is between 0:0.01 and 1:1000.
